(19) United States
(12) Patent Application Publication
(10) Pub. No.: US 2026/0101696 A1
(43) Pub. Date: Apr. 9, 2026

(54) SUBSTRATE PROCESSING APPARATUS AND SUBSTRATE PROCESSING METHOD

(71) Applicant: Tokyo Electron Limited, Tokyo (JP)

(72) Inventor: Gentaro GOSHI, Kumamoto (JP)

(73) Assignee: Tokyo Electron Limited, Tokyo (JP)

(21) Appl. No.: 19/332,046

(22) Filed: Sep. 18, 2025

(30) Foreign Application Priority Data
Oct. 4, 2024 (JP) 2024-175339

(51) Int. Cl. H01L 21/67; G01N 9/00

(52) U.S. Cl. CPC H10P 72/0408; G01N 9/00

(57) ABSTRACT

A substrate processing apparatus includes a container executing a drying process including a raising process for raising a pressure in the container, on a substrate housed therein; a pressure detecting unit detecting a pressure of process fluid in the container; a temperature detecting unit detecting a temperature of the process fluid in the container; and a controller including: a first unit calculating a density of the process fluid based on a first pressure and a first temperature detected in the raising process executed without drying liquid; a second unit that calculates a density of the process fluid based on a second pressure and a second temperature detected in the raising process executed with the drying liquid; a difference calculating unit calculating difference between the first and second densities; and a determining unit determining, based on the difference, appropriateness of a state of the liquid film.

### CROSS-REFERENCE TO RELATED APPLICATION

This application is based upon and claims the benefit of priority of the prior Japanese Patent Application No. 2024-175339, filed on Oct. 4, 2024, the entire contents of which are incorporated herein by reference.

### FIELD

Exemplary embodiments disclosed herein relate to a substrate processing apparatus and a substrate processing method.

### BACKGROUND

Conventionally, there has been known a supercritical drying process for bringing a substrate, which is in a state where a surface of the substrate is wet with drying liquid, into contact with process fluid in a supercritical state to replace the drying liquid with the process fluid, so as to dry the substrate.

Patent Application Laid-open No. 2022-043882 includes a pressure vessel that accommodates therein a substrate, a discharge line that discharges internal fluid of the pressure vessel, and a concentration measuring unit that measures the concentration of drying liquid in fluid flowing through the discharge line. The above-mentioned substrate processing apparatus detects abnormality in a liquid amount of a liquid film of drying liquid formed on the substrate on the basis of a concentration of the drying liquid, which is measured by the concentration measuring unit.

However, the above-mentioned conventional technology is a technology for measuring a concentration of drying liquid occupied in fluid flowing through a discharge line, so that it is difficult to detect abnormality in a liquid film in a state where the discharge line is closed. Moreover, it is difficult for the above-mentioned conventional technology to detect abnormality in the liquid film at a step before replacement of the drying liquid with process fluid starts. Thus, for example, it is difficult to detect abnormality in a liquid film state in a process that is executed before replacement of the drying liquid with the process fluid starts, specifically, a pressure raising process for supplying the process fluid to a pressure vessel under a state where the discharge line is closed so as to raise the pressure in the pressure vessel.

### SUMMARY

A substrate processing apparatus according to one aspect of the present disclosure includes a processing container, a pressure detecting unit, a temperature detecting unit, and a controller. Into the processing container, process fluid is supplied and a liquid film of drying liquid formed on a substrate is replaced with the process fluid in a supercritical state to execute a drying process on the substrate. The drying process includes a pressure raising process for supplying the process fluid into the processing container so as to raise an internal pressure of the processing container up to a set pressure equal to or more than a critical pressure. The pressure detecting unit detects a pressure of the process fluid in the processing container. The temperature detecting unit detects a temperature of the process fluid in the processing container. The controller includes a first density calculating unit that calculates first density data indicating a time-dependent change in a density of the process fluid based on a first pressure detected by the pressure detecting unit and a first temperature detected by the temperature detecting unit in the pressure raising process of preprocessing that is the drying process executed in a state where a liquid film of the drying liquid is not formed on the substrate. The controller includes a second density calculating unit that calculates second density data indicating a time-dependent change in a density of the process fluid based on a second pressure detected by the pressure detecting unit and a second temperature detected by the temperature detecting unit in the pressure raising process of a main process that is the drying process executed in a state where a liquid film of the drying liquid is formed on the substrate. The controller includes a density difference calculating unit that calculates density difference data that is difference between the first density data and the second density data. The controller includes an appropriateness determining unit that determines, based on the density difference data and in the main process, appropriateness of the state of the liquid film of the drying liquid formed on the substrate.

### BRIEF DESCRIPTION OF DRAWINGS

FIG. 1 is a schematic top view illustrating a substrate processing system according to a first embodiment;

FIG. 2 is a schematic side view illustrating the substrate processing system according to the first embodiment;

FIG. 3 is a flowchart illustrating a series of substrate processing procedures to be executed in the substrate processing system according to the first embodiment;

FIG. 4 is a schematic diagram illustrating a transferring procedure of a wafer;

FIG. 5 is a schematic diagram illustrating a configuration example of a liquid processing unit according to the first embodiment;

FIG. 6 is a schematic diagram illustrating a configuration example of a drying unit according to the first embodiment;

FIG. 7 is a schematic diagram illustrating a piping configuration example of the drying unit according to the first embodiment;

FIG. 8 is a flowchart illustrating a drying process to be executed in the substrate processing system according to the first embodiment;

FIG. 9 is a schematic diagram illustrating an internal state of a processing container in the pressure raising process;

FIG. 10 is a functional block diagram illustrating a configuration example of a control device according to the first embodiment;

FIG. 11 is a diagram illustrating one example of relation between a density, a pressure, and a temperature in supercritical fluid;

FIG. 12 is a diagram illustrating one example of first density data;

FIG. 13 is a diagram illustrating one example of second density data;

FIG. 14 is a diagram illustrating one example of density difference data;

FIG. 15 is a diagram illustrating an example of data to be stored in a storage according to the first embodiment;

FIG. 16 is a flowchart illustrating a procedure for a series of abnormality detections to be executed in a controller according to the first embodiment;

FIG. 17 is a diagram illustrating one example of density difference data including abnormality in the drying process;

FIG. 18 is a flowchart illustrating a procedure for appropriateness determination to be executed in an appropriateness determining unit according to the first embodiment;

FIG. 19 is a functional block diagram illustrating a configuration example of a control device according to a second embodiment;

FIG. 20 is a flowchart illustrating a procedure for a series of abnormality detections to be executed in a controller according to the second embodiment; and

FIG. 21 is a flowchart illustrating a procedure for estimation determination to be executed by a prediction determining unit according to the second embodiment.

### DESCRIPTION OF EMBODIMENTS

Hereinafter, modes (hereinafter, may be referred to as “embodiments”) for practicing a substrate processing apparatus and a substrate processing method according to the present disclosure will be described in detail with reference to the accompanying drawings. In addition, the illustrative embodiments disclosed below are not intended to limit the disclosed technology. Note that any of the embodiments can be appropriately combined with each other within a consistency range. Hereinafter, the same reference symbol is provided to the same part in the following embodiments so as to omit duplicated explanation.

For convenience of explanation, in the following drawings to be mentioned later, an X-axis direction, a Y-axis direction, and a Z-axis direction that are perpendicular to one another are defined, and further an orthogonal coordinate system whose Z-axis direction is the vertical upward direction may be indicated.

### Configuration of Substrate Processing System

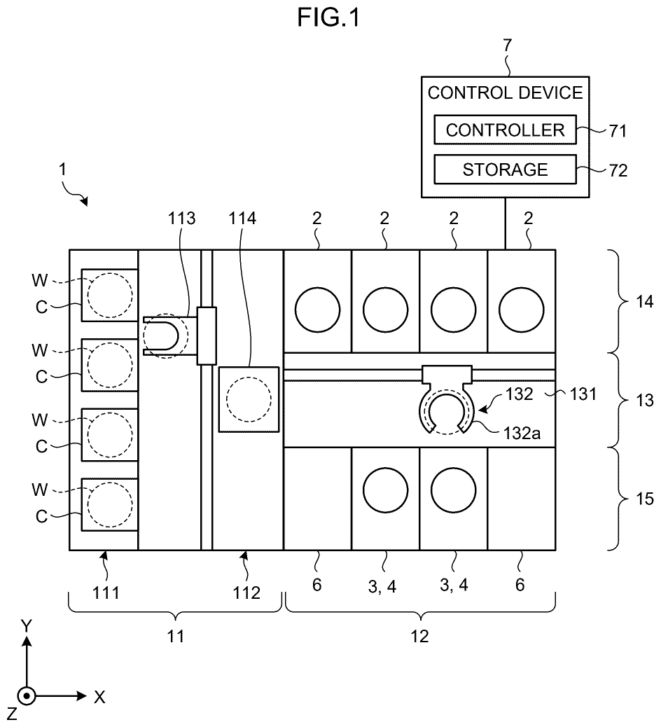

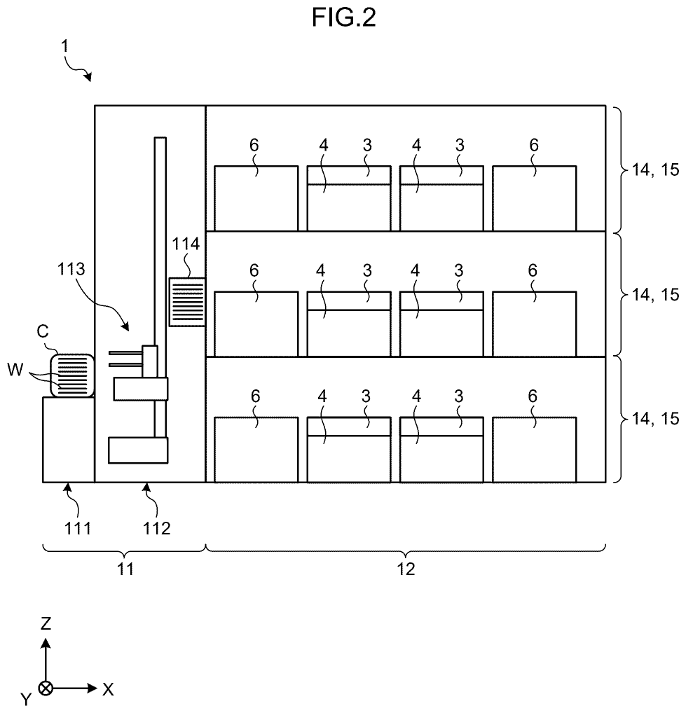

A configuration of a substrate processing system (one example of substrate processing apparatus) according to the present embodiment will be first explained with reference to FIG. 1 and FIG. 2. FIG. 1 is a schematic top view illustrating a substrate processing system according to the first embodiment. FIG. 2 is a schematic side view illustrating the substrate processing system according to the first embodiment.

As illustrated in FIG. 1, a substrate processing system 1 includes a carry-in/out station 11 and a processing station 12. The carry-in/out station 11 and the processing station 12 are adjacently arranged to each other.

The carry-in/out station 11 includes a carrier placing section 111 and a transfer section 112. A plurality of carriers C is placed in the carrier placing section 111, each of which accommodates therein a plurality of semiconductor wafers W (hereinafter, may be referred to as “wafers W”) in a horizontal state.

The transfer section 112 is adjacently arranged to the carrier placing section 111. A transfer device 113 and a delivery unit 114 are arranged in the transfer section 112.

The transfer device 113 includes a wafer holding mechanism that is configured to hold the wafer W. The transfer device 113 is capable of moving in a horizontal direction and a vertical direction, and further turning around a vertical axis so as to transfer the wafer W between the carrier C and the delivery unit 114 by using the wafer holding mechanism.

The wafer W is temporarily placed on the delivery unit 114.

The processing station 12 is adjacently arranged to the transfer section 112. The processing station 12 includes a transfer block 13, a first processing block 14, and a second processing block 15.

The transfer block 13 includes a transfer area 131 and a transfer device 132. The transfer area 131 is a rectangular-parallelepiped region that extends along an alignment direction (namely, X-axis direction) of the carry-in/out station 11 and the processing station 12, for example. The transfer device 132 is arranged in the transfer area 131.

The transfer device 132 includes a wafer holding mechanism 132a that is configured to hold the wafer W. The transfer device 132 is capable of moving in a horizontal direction and a vertical direction, and further turning around a vertical axis so as to transfer the wafer W between the delivery unit 114, the first processing block 14, and the second processing block 15 by using the wafer holding mechanism 132a.

The first processing block 14 and the second processing block 15 are arranged on both sides of the transfer area 131 adjacently to the transfer area 131. For one example, the first processing block 14 is arranged on one side (side of Y-axis positive direction) of the transfer area 131 in a direction (namely, Y-axis direction) perpendicular to an alignment direction (namely, X-axis direction) of the carry-in/out station 11 and the processing station 12. The second processing block 15 is arranged on the other side (side of Y-axis negative direction) of the transfer area 131 in a direction (namely, Y-axis direction) perpendicular to an alignment direction (namely, X-axis direction) of the carry-in/out station 11 and the processing station 12.

As illustrated in FIG. 2, the plurality of first processing blocks 14 and the plurality of second processing blocks 15 may be arranged along a vertical direction in a multistage manner. In the first embodiment, the step numbers of the plurality of first processing blocks 14 and the plurality of second processing blocks 15 are respectively three; however, the step numbers of the plurality of first processing blocks 14 and the plurality of second processing blocks 15 are not respectively limited to three.

As described above, in the substrate processing system 1 according to the embodiments, the plurality of first processing blocks 14 and the plurality of second processing blocks 15 may be respectively arranged in a multistage manner on both sides of the transfer block 13. The wafer W may be transferred between the first processing block 14 and the second processing block 15 that are arranged in each stage by the single transfer device 132 arranged in the transfer block 13.

The first processing block 14 includes a plurality of liquid processing units 2.

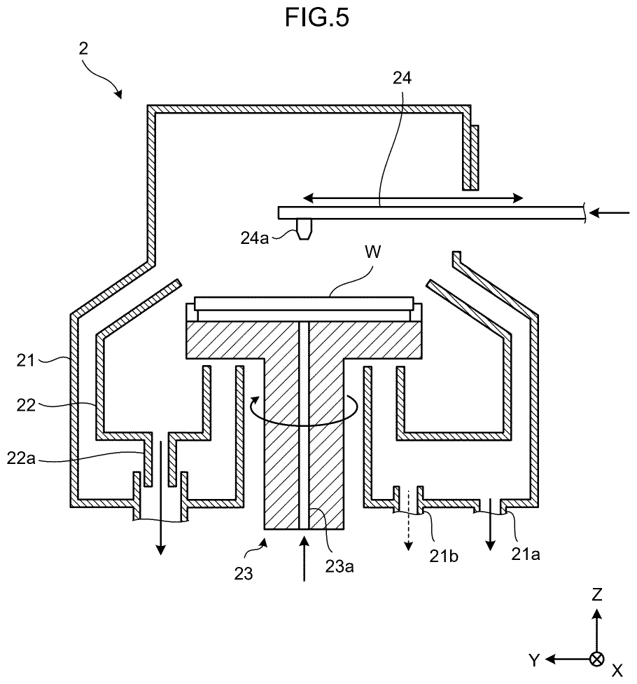

Each of the liquid processing units 2 executes a cleaning process for cleaning an upper surface that is a pattern-formed surface of the wafer W. The liquid processing unit 2 executes a liquid-film forming process for supplying isopropyl alcohol (IPA) liquid (one example of drying liquid) to an upper surface of the cleaning-processed wafer W so as to form thereon a liquid film. A configuration of the liquid processing unit 2 will be mentioned later with reference to FIG. 5.

The second processing block 15 includes a plurality of measurement units 3, a plurality of drying units 4, and a plurality of supply units 6.

Each of the measurement units 3 measures a weight of the wafer W. Specifically, the measurement unit 3 measures weights of the wafer W before and after a liquid-film forming process, for example. In the first embodiment, the measurement units 3 are arranged on or above the drying units 4 (see FIG. 2).

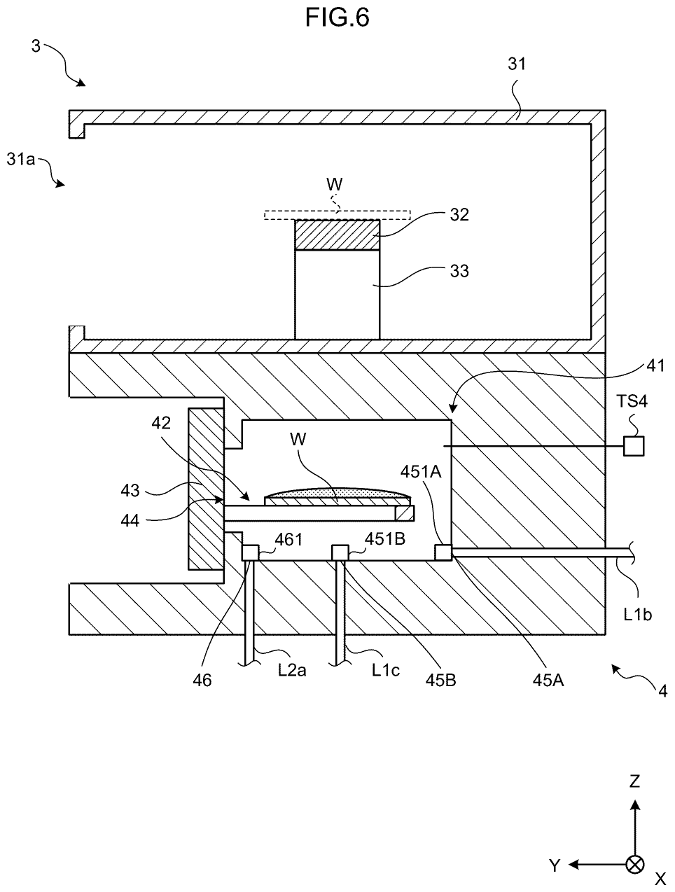

Each of the drying units 4 executes a supercritical drying process on the liquid-film forming processed wafer W (hereinafter, may be referred to as “drying process”). Specifically, the drying unit 4 brings the liquid-film forming processed wafer W into contact with process fluid in a supercritical state so as to dry the above-mentioned wafer W. A configuration of the drying unit 4 will be mentioned later with reference to FIG. 6. Note that hereinafter, process fluid in a supercritical state may be referred to as supercritical fluid.

The supply unit 6 supplies process fluid to the drying unit 4. Specifically, the supply unit 6 includes a supply device group, which includes a flowmeter, a flow controller, a back pressure valve, a heater, and the like; and a housing that accommodates therein the supply device group. In the present embodiment, the supply unit 6 supplies CO₂ to the drying unit 4 as process fluid.

As illustrated in FIG. 2, the measurement units 3 and the drying units 4 are arranged in an overlapped manner in a vertical direction. As one example, the measurement units 3 are arranged on or above the drying units 4 in an overlapped manner. The measurement units 3 may be arranged under the drying units 4 in an overlapped manner. The measurement units 3 and the drying units 4 are arranged in an overlapped manner in a vertical direction so as to reduce an arrangement area of the second processing block 15.

The substrate processing system 1 includes a control device 7. The control device 7 is a computer, for example, and further includes a controller 71 and a storage 72.

The controller 71 includes a micro-computer including a Central Processing Unit (CPU), a Read Only Memory (ROM), a Random Access Memory (RAM), an input/output port, and the like; and various circuits. The CPU of the micro-computer reads and executes a program stored in the ROM so as to realize controlling on the transfer devices 113 and 132, the liquid processing units 2, the drying units 4, the supply units 6, etc.

The above-mentioned program may be recorded in a computer-readable recording medium, and further may be installed in the storage 72 of the control device 7 from the above-mentioned recording medium. As the computer-readable recording medium, for example, a hard disk (HD), a flexible disk (FD), a compact disk (CD), a magnet-optical disk (MO), a memory card, or the like may be employed.

The storage 72 is realized by a semiconductor memory element such as a RAM and a flash memory, or a storage device such as a hard disk and an optical disk.

### Substrate Processing Procedure

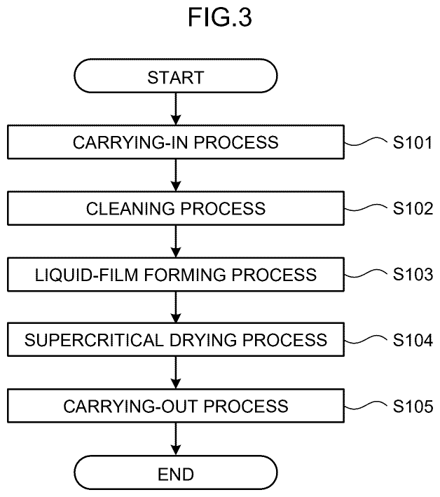

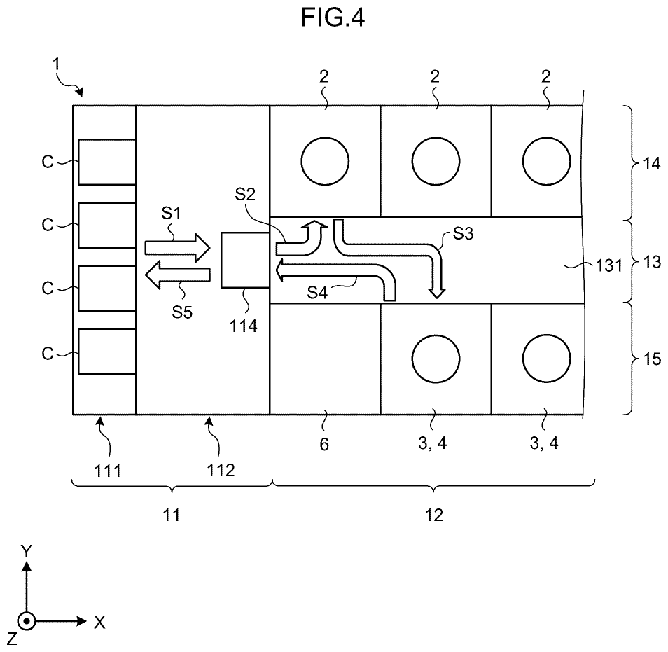

Next, the transferring procedure and the series of substrate processing procedures of the wafer W in the above-mentioned substrate processing system 1 will be explained with reference to FIG. 3 and FIG. 4. FIG. 3 is a flowchart illustrating a series of substrate processing procedures to be executed in the substrate processing system 1 according to the first embodiment. FIG. 4 is a schematic diagram illustrating a transferring procedure of the wafer W. Note that a series of substrate processing illustrated in FIG. 3 is executed in accordance with controlling by the controller 71.

As illustrated in FIG. 3, in the substrate processing system 1, a carrying-in process is first executed (Step S101). In the carrying-in process, the transfer device 113 (see FIG. 1) takes the wafer W out of the carrier C, and further places the wafer W on the delivery unit 114 (see procedure S1 illustrated in FIG. 4).

Next, the transfer device 132 (see FIG. 1) takes the wafer W out of the delivery unit 114, and further carries the wafer W into the liquid processing unit 2 (see procedure S2 illustrated in FIG. 4).

Next, in the substrate processing system 1, a cleaning process is executed in the liquid processing unit 2 (Step S102). The liquid processing unit 2 supplies various processing liquids to an upper surface of the wafer W, which is a pattern-formed surface, so as to remove particles, a natural oxide film, and the like from the upper surface of the wafer W.

Next, in the substrate processing system 1, a liquid-film forming process is executed in the liquid processing unit 2 (Step S103). The liquid processing unit 2 supplies IPA in a liquid state to an upper surface of the cleaning-processed wafer W so as to form a liquid film of IPA on an upper surface of the wafer W.

Although illustration thereof is omitted in FIG. 3 and FIG. 4, for example, the measurement unit 3 may measure weights of the wafer W before and after a liquid-film forming process of Step S103. This point will be mentioned later with reference to FIG. 6. In this case, the wafer W may be appropriately carried into/from the measurement units 3 by the transfer device 132 (see FIG. 1).

The liquid-film forming processed wafer W is transferred from the liquid processing unit 2 to the drying unit 4 by the transfer device 132 (see procedure S3 illustrated in FIG. 4).

Next, in the substrate processing system 1, a drying process starts in the drying unit 4 (Step S104). In the drying process, the drying unit 4 brings the liquid-film formed wafer W into in contact with process fluid in a supercritical state so as to dry the wafer W. For example, in a case where a preset drying time interval has elapsed, the controller 71 ends the drying process.

Next, in the substrate processing system 1, a carrying-out process is executed (Step S105). In the carrying-out process, the transfer device 132 takes the drying-processed wafer W out of the drying unit 4, and further transfers the wafer W into the delivery unit 114 (see procedure S4 illustrated in FIG. 4). Next, the transfer device 113 takes the drying-processed wafer W out of the delivery unit 114, and further transfers the wafer W into the carrier C (see procedure S5 illustrated in FIG. 4). In a case where the carrying-out process has ended, a series of substrate processing with respect to the single wafer W has ended.

### Configuration of Liquid Processing Unit

A configuration of the liquid processing unit 2 will be explained with reference to FIG. 5. FIG. 5 is a schematic diagram illustrating a configuration example of the liquid processing unit 2 according to the first embodiment. The liquid processing unit 2 is configured as a single-wafer-processing type cleaning device that cleans the wafer W one-by-one by spin cleaning, for example.

As illustrated in FIG. 5, the liquid processing unit 2 causes a wafer holding mechanism 23, which is arranged in an outer chamber 21 forming a processing space, to substantially and horizontally hold the wafer W, and further causes the wafer holding mechanism 23 to rotate around a vertical axis so as to rotate the wafer W. The liquid processing unit 2 causes a nozzle arm 24 to enter the above of the rotating wafer W, and further supplies chemical liquid and rinse liquid from a chemical liquid nozzle 24a that is arranged in a leading end of the nozzle arm 24 in a predetermined order, so as to execute a cleaning process on an upper surface of the wafer W.

In the liquid processing unit 2, a chemical-liquid supplying route 23a is formed in the wafer holding mechanism 23. A lower surface of the wafer W is also cleaned by chemical liquid and rinse liquid that are supplied from the chemical-liquid supplying route 23a.

For example, the cleaning process includes first removing particles and organic contaminants by using SC1 liquid (namely, mixed solution of ammonia and hydrogen peroxide) that is alkaline chemical liquid, and then executing rinse cleaning by using deionized water (DeIonized Water: hereinafter, may be referred to as “DIW”) by using rinse liquid. Next, removal of a natural oxide film is executed by using diluted hydrofluoric acid aqueous solution (Diluted HydroFluoric acid: hereinafter, may be referred to as “DHF”) that is acidic chemical liquid so as to execute rinse cleaning with the use of DIW.

The above-mentioned various chemical liquids are received by an inner cup 22 that is arranged in the outer chamber 21 and the outer chamber 21, and further are discharged from a drain port 21a arranged in a bottom portion of the outer chamber 21 and a drain port 22a arranged in a bottom portion of the inner cup 22. Furthermore, atmosphere in the outer chamber 21 is discharged from an discharge port 21b arranged in a bottom portion of the outer chamber 21.

A liquid-film forming process is executed after the rinsing process in the cleaning process. Specifically, the liquid processing units 2 supplies IPA to an upper surface and a lower surface of the wafer W while rotating the wafer holding mechanism 23. Thus, DIW remaining on both surfaces of the wafer W is replaced with IPA. Next, the liquid processing unit 2 gradually stops rotation of the wafer holding mechanism 23.

The liquid-film forming processed wafer W is transferred to the transfer device 132 by a not-illustrated transferring mechanism arranged in the wafer holding mechanism 23 in a state where a liquid film of IPA is formed on an upper surface of the wafer W, and further is carried out of the liquid processing unit 2. In a liquid film formed on the wafer W, it is possible to prevent liquid on an upper surface of the wafer W from vaporizing during a transferring operation and/or a carrying-in operation of the wafer W from the liquid processing unit 2 to the drying unit 4, which causes pattern collapse.

### Configuration of Drying Unit

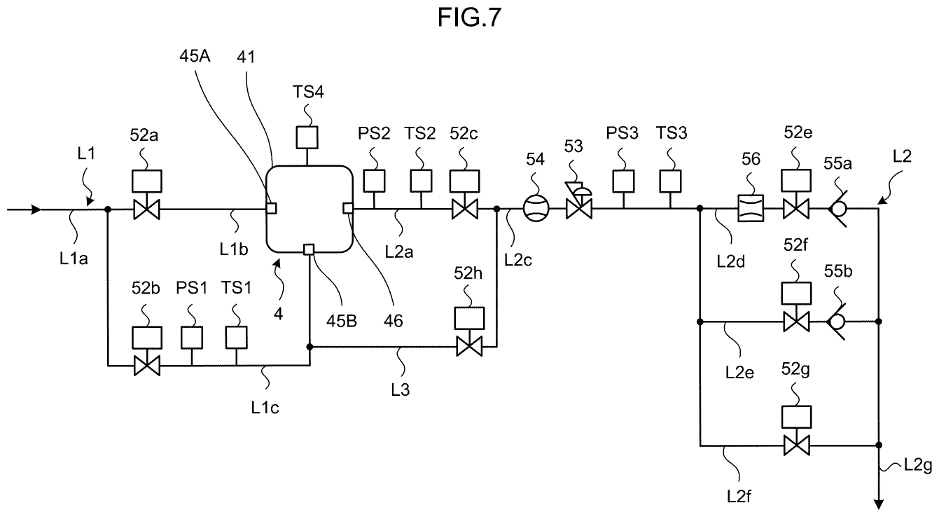

A configuration of the drying unit 4 will be explained with reference to FIG. 6 and FIG. 7. FIG. 6 is a schematic diagram illustrating a configuration example of the drying unit 4 according to the first embodiment. FIG. 7 is a schematic diagram illustrating a piping configuration example of the drying unit 4 according to the first embodiment.

The drying unit 4 executes the above-mentioned drying process. The drying unit 4 replaces a liquid film of IPA, which is formed on the wafer W, with process fluid (namely, supercritical fluid) in a supercritical state so as to dry the wafer W. The supercritical fluid is fluid in a state where liquid and gas are indistinguishable from each other at a temperature equal to or more than a critical temperature thereof and at a pressure equal to or more than a critical pressure thereof. In a case where IPA is replaced with supercritical fluid, it is possible to prevent appearance of an interface between liquid and gas in an unevenness pattern of the wafer W. As a result, generation of surface tension can be avoided to be able to prevent collapse of the unevenness pattern. The supercritical fluid is CO₂, for example.

As illustrated in FIG. 6, the drying unit 4 includes a processing container 41, a holding unit 42, and a lid body 43. The processing container 41 accommodates therein the wafer W on which a liquid film of IPA is formed. In the processing container 41, there are formed an opening 44 for carrying-in/out the wafer W, supply ports 45A and 45B for connecting to a supply line L1 to be mentioned later, and a discharge port 46 for connecting to a discharge line L2 to be mentioned later.

On a side surface of the processing container 41, a temperature sensor TS4 (one example of temperature detecting unit) is arranged. The temperature sensor TS4 detects a temperature of process fluid in the processing container 41. Information on the detected temperature is output to the controller 71.

Note that in the first embodiment, a case is exemplified where the single temperature sensor TS4 alone is arranged on a side surface of the processing container 41; however, a plurality of temperature sensors may be provided to the processing container 41. For example, the plurality of temperature sensors may be arranged on a side surface that is different from the side surface on which the temperature sensor TS4 is arranged; an upper surface of the processing container 41; and the like. In this case, an average value obtained by the plurality of temperature sensors may be detected as a temperature of the process fluid.

The holding unit 42 holds the wafer W in a horizontal direction. For example, the holding unit 42 is formed in rectangular-shaped in a plan view, and further supports a peripheral portion of the wafer W from the below so as to hold the wafer W. The holding unit 42 is capable of turning/lifting upward/downward by a not-illustrated turning/lifting device that is provided to the lid body 43 to be mentioned later. According to the above-mentioned configuration, in a case where the wafer W is turned/lifted in the processing container 41, it is possible to adjust a gap between an upper surface of the processing container 41 and a liquid film of IPA formed on an upper surface of the wafer W.

The lid body 43 supports the holding unit 42. As described above, the lid body 43 includes a not-illustrated turning/lifting device for turning/lifting upward/downward the holding unit 42. The lid body 43 is connected with a not-illustrated movement mechanism, and further is in a “processing position” in a processing container and in a position outside the processing container by the above-mentioned movement mechanism to be capable of horizontally moving to a “first carry-in/carry-out position” where the wafer W is transferred between the transfer device 132 and the holding unit 42. In a case where the lid body 43 moves to the processing position, the holding unit 42 is arranged in the processing container 41 so as to cause the lid body 43 to close the opening 44 of the processing container 41.

Herein, a configuration of the measurement unit 3 will be explained. As illustrated in FIG. 6, in the first embodiment, the measurement unit 3 is arranged on the drying unit 4. The measurement unit 3 includes a case 31, a weight sensor 32, and a support member 33, for example. An opening 31a is formed in the case 31, which is for carrying-in/out the wafer W by the transfer device 132.

The weight sensor 32 horizontally supports the wafer W so as to measure a weight of the wafer W. For example, as described above, the weight sensor 32 may measure weights of the wafer W before and after a liquid-film forming process executed by the liquid processing unit 2. In other words, the weight sensor 32 individually measures a weight of the wafer W on which a liquid film of IPA is not formed, and a weight of the wafer W on which a liquid film of IPA is formed. By using the above-mentioned measurement values measured by the weight sensor 32, the controller 71 may calculate a liquid amount of a liquid film of IPA formed in the liquid-film forming process.

The support member 33 is arranged such that the supports member 33 erects from a bottom portion of the case 31, so as to support the weight sensor 32 from the below. Note that the measurement unit 3 including the weight sensor 32 and the support member 33 is provided to each of the plurality of drying units 4, for example, so as to individually measure a weight of the wafer W transferred in the corresponding drying unit 4.

The supply port 45A is connected with a side surface on an opposite side of the opening 44 in the processing container 41. The supply port 45B is connected with a bottom surface of the processing container 41. Moreover, the discharge port 46 is connected with a portion under the opening 44. Note that the two supply ports 45A and 45B and the single discharge port 46 are illustrated in FIG. 6 and FIG. 7; however, the numbers and positions of the supply ports 45A and 45B and the discharge port 46 are not limited thereto.

Supply headers 451A and 451B and a discharge header 461 are arranged in the processing container 41. Not-illustrated many openings are formed in each of the supply headers 451A and 451B and the discharge header 461.

The supply header 451A is connected to the supply port 45A, and further is adjacently arranged to a side surface on an opposite side of the opening 44 in the processing container 41. Many openings formed in the supply header 451A are facing the opening 44, for example.

The supply header 451B is connected to the supply port 45B, and further is arranged in a central portion of a bottom surface in the processing container 41. Many openings formed in the supply header 451B are facing upward, for example.

The discharge header 461 is connected to the discharge port 46, is adjacently arranged to a side surface on a side of the opening 44 in the processing container 41, and further is arranged lower than the opening 44. Many openings formed in the discharge header 461 are facing a supply header 451, for example.

The supply headers 451A and 451B supply process fluid into the processing container 41. The discharge header 461 discharges process fluid and IPA into the processing container 41.

As illustrated in FIG. 7, the drying unit 4 is connected to the supply line L1, which supplies process fluid to the drying unit 4, and the discharge line L2 that discharges process fluid and IPA from the drying unit 4. The supply line L1 connects a fluid supply source and the processing container 41 to each other. Process fluid is supplied to the supply line L1 from the fluid supply source. Not-illustrated heater is provided to the supply line L1. The heater maintains process fluid supplied to the processing container 41 to be equal to more than a critical temperature. The heater is provided over whole of the supply line L1, for example.

The supply line L1 includes a common line L1a, a distribution line L1b, and a pressure-raising line L1c. An upper-stream end of the common line L1a is connected to a fluid supply source, a lower-stream end of the common line L1a is connected to the distribution line L1b and the pressure-raising line L1c. The distribution line L1b is connected to the supply port 45A, and the pressure-raising line L1c is connected to the supply port 45B.

An open/close valve 52a is arranged on the distribution line L1b. The open/close valve 52a opens/closes a flow path of fluid. In a case where the open/close valve 52a opens a flow path, process fluid is supplied into the processing container 41 via the supply port 45A and the supply header 451A (see FIG. 6). On the other hand, in a case where the open/close valve 52a closes the flow path, supplying of process fluid to the processing container 41 is stopped.

Similarly, an open/close valve 52b, a pressure sensor PS1, and a temperature sensor TS1 are arranged on the pressure-raising line L1c. The open/close valve 52b opens/closes a flow path of fluid. In a case where the open/close valve 52b opens a flow path, process fluid is supplied into the processing container 41 via the supply port 45B and the supply header 451B (see FIG. 6). On the other hand, in a case where the open/close valve 52b closes a flow path, supplying of process fluid to the processing container 41 is stopped. The pressure sensor PS1 detects a pressure of fluid flowing through the pressure-raising line L1c. The temperature sensor TS1 detects a temperature of fluid flowing through the pressure-raising line L1c.

The pressure-raising line L1c is connected to a bypass line L3 on a lower flow side of the open/close valve 52b, the pressure sensor PS1, and the temperature sensor TS1. An open/close valve 52 is arranged on the bypass line L3. An open/close valve 52h opens/closes a flow path of fluid. In a case where the open/close valve 52h opens a flow path, a part of process fluid flowing through the pressure-raising line L1c is led to the discharge line L2 via the bypass line L3. Thus, it is possible to reduce a supply flow volume of process fluid to be supplied into the processing container 41.

Note that in the first embodiment, the distribution line L1b and the pressure-raising line L1c are separately provided; however, may be integrally provided.

The discharge line L2 includes an open/close line L2a, a first common line L2c, a first intermediate line L2d, a second intermediate line L2e, a third intermediate line L2f, and a second common line L2g, for example.

The open/close line L2a extends from the discharge port 46 of the processing container 41 to an upper-stream end of the first common line L2c. An open/close valve 52c, a pressure sensor PS2 (one example of pressure detecting unit), and a temperature sensor TS2 are arranged on the open/close line L2a. The open/close valve 52c opens/closes a flow path of fluid. In a case where the open/close valve 52c opens a flow path, fluid in the processing container 41 is discharged to the outside of the substrate processing system 1 via the discharge header 461 (see FIG. 6) and the discharge port 46. On the other hand, in a case where the open/close valve 52c closes a flow path, discharging of fluid from the processing container 41 is stopped.

The pressure sensor PS2 detects a pressure of fluid flowing through the open/close line L2a. The above-mentioned pressure sensor PS2 is arranged on the open/close line L2a on an upper flow side than the open/close valve 52c. Thus, in a case where the open/close valve 52c is closed, the pressure sensor PS2 is capable of detecting a pressure of process fluid in the processing container 41. Information on the detected pressure is output to the controller 71. The temperature sensor TS2 detects a temperature of fluid flowing through the open/close line L2a.

A decompression valve 53, a flowmeter 54, a pressure sensor PS3, and a temperature sensor TS3 are arranged on the first common line L2c. The decompression valve 53 reduces a pressure of fluid on a lower flow side than the decompression valve 53 into a smaller one than a pressure of the fluid of an upper flow side than the decompression valve 53. The pressure on an upper flow side than the decompression valve 53 is 4 MPa to 18 MPa, for example, and the pressure on a lower flow side than the decompression valve 53 is 0.1 MPa to 0.5 MPa, for example. The flowmeter 54 measures a flow volume of the fluid before decompression; however, may measure a flow volume of the fluid after decompression. The pressure sensor PS3 detects a pressure of fluid flowing through the first common line L2c. The temperature sensor TS3 detects a temperature of fluid flowing through the first common line L2c.

A lower-stream end of the bypass line L3 is connected to an upper-stream end of the first common line L2c. Thus, for example, in a case where an opening degree of the decompression valve 53 is adjusted in a state where the open/close valve 52c is closed and the open/close valve 52h is opened, a part of process fluid flowing through the pressure-raising line L1c can be discharged to the outside of the processing container 41. Thus, it is possible to adjust a supply flow volume of process fluid to be supplied into the processing container 41.

For example, in a case where an opening degree of the decompression valve 53 is adjusted in a state where the open/close valve 52c is opened and the open/close valve 52h is closed, it is possible to adjust an discharge flow volume of process fluid to be discharged from the processing container 41 via the open/close line L2a.

Each of the first intermediate line L2d, the second intermediate line L2e, and the third intermediate line L2f extends from a lower-stream end of the first common line L2c to an upper-stream end of the second common line L2g.

An open/close valve 52e, a check valve 55a, and an orifice 56 are arranged on the first intermediate line L2d. The open/close valve 52e opens/closes a flow path of fluid. In a case where the open/close valve 52e opens a flow path, fluid in the processing container 41 is discharged to the outside of the substrate processing system 1 through the open/close valve 52e. On the other hand, in a case where the open/close valve 52e closes a flow path, discharging of fluid via the first intermediate line L2d is stopped. The check valve 55a prevents backflow of fluid. The orifice 56 reduces a pressure of process fluid flowing through a pipe on a lower flow side down to a desired value.

Similarly, an open/close valve 52f and a check valve 55b are arranged on the second intermediate line L2e. The open/close valve 52f opens/closes a flow path of fluid. In a case where the open/close valve 52f opens a flow path, fluid in the processing container 41 is discharged to the outside of the substrate processing system 1 via the open/close valve 52f. On the other hand, in a case where the open/close valve 52f closes a flow path, discharging of fluid via the second intermediate line L2e is stopped. The check valve 55b prevents backflow of fluid.

An open/close valve 52g is arranged on the third intermediate line L2f. The open/close valve 52g opens/closes a flow path of fluid. In a case where the open/close valve 52g opens a flow path, fluid in the processing container 41 is discharged to the outside of the substrate processing system 1 via the open/close valve 52g. On the other hand, in a case where the open/close valve 52g closes a flow path, discharging of fluid via the third intermediate line L2f is stopped.

The first intermediate line L2d, the second intermediate line L2e, and the third intermediate line L2f are separately provided; however, may be integrally provided. Note that in the former case, fluid is discharged via the plurality of open/close valves 52e, 52f, and 52g to be capable of finely controlling a discharge flow volume of the fluid.

### Method for Drying Process

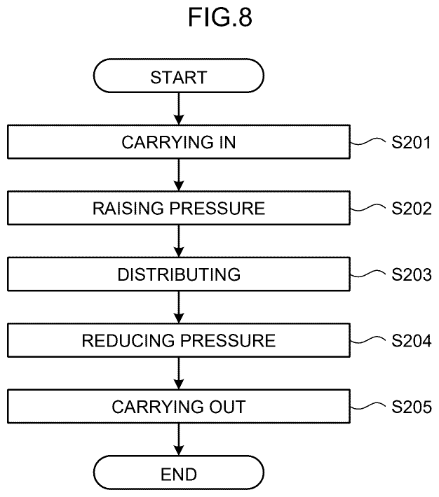

A procedure for a drying process will be explained with reference to FIG. 8. FIG. 8 is a flowchart illustrating a drying process to be executed in the substrate processing system 1 according to the first embodiment. Steps S201 to S205 illustrated in FIG. 8 are executed under control of the controller 71.

In Step S201, a not-illustrated transfer device carries the wafer W, on which a liquid film of IPA is formed, into the drying unit 4. The holding unit 42 receives the wafer W from the transfer device, and further horizontally holds the wafer W in a state where a liquid film of IPA thereof is facing upward. The wafer W is housed in the processing container 41, and the lid body 43 closes the opening 44 of the processing container 41.

Next, in Step S202, the supply line L1 supplies process fluid into the processing container 41 via the supply port 45B and the supply header 451B so as to raise an inner pressure of the processing container 41. In this case, process fluid is supplied from the below of the wafer W so as not to disturb a liquid film of IPA formed on the wafer W. Thus, a pressure in the processing container 41 rises up to a set pressure that is equal to or more than a critical pressure. Hereinafter, the above-mentioned Step S202 may be referred to as a pressure raising process.

The above-mentioned pressure raising process includes a first pressure raising process for raising a pressure in the processing container 41 while discharging, from the processing container 41, a part of process fluid supplied to the processing container 41; and a second pressure raising process for raising, after the first pressure raising process, a pressure in the processing container 41 up to a set pressure equal to or more than a critical pressure in a state where discharging of the process fluid from the processing container 41 is stopped.

Specifically, in the first pressure raising process, process fluid is supplied into the processing container 41 via the supply line L1 in a state where the open/close valve 52c is closed and the open/close valve 52h is opened. Thus, it is possible to supply process fluid into the processing container 41 while reducing a supply flow volume of the process fluid.

In the first pressure raising process, a pressure of process fluid supplied via the supply line L1 largely reduces when flowing into the processing container 41 that is in an ordinary pressure state and whose volume is comparatively large. Thus, the process fluid enters the processing container 41 at a high flow speed. Therefore, there presents possibility that the process fluid collides with a liquid film of IPA so that liquid of IPA falls down from an upper surface of the wafer W. In a case where process fluid is supplied while reducing a supply flow volume of the process fluid, it is possible to prevent the IPA from falling down. Note that in the first pressure raising process, a pressure of process fluid in the processing container 41 is lower than a critical pressure (for example, approximately 8 MPa), and thus the process fluid is in a gas state.

In the second pressure raising process, process fluid is supplied to the processing container 41 via the supply line L1 in a state where the open/close valve 52c and the open/close valve 52h are closed. In other words, process fluid is supplied to the processing container 41 in a state where discharging of process fluid from the processing container 41 is stopped. Thus, a pressure in the processing container 41 rises up to a set pressure that is equal to or more than a critical pressure.

In Step S203, the supply line L1 supplies process fluid into the processing container 41 via the supply port 45A and the supply header 451A while the discharge line L2 is discharging internal fluid of the processing container 41, so as to cause the process fluid (namely, supercritical fluid) in a supercritical state to flow through the above of the wafer W. IPA dissolved in the supercritical fluid is discharged to the outside of the processing container 41, and a liquid film of IPA on the wafer W is replaced with the supercritical fluid, so as to dry the wafer W. Note that in Step S203, a pressure in the processing container 41 is maintained to be the above-mentioned set pressure.

In Step S204, the supply line L1 stops supplying process fluid into the processing container 41, and the discharge line L2 discharges internal fluid of the processing container 41, so as to reduce a pressure in the processing container 41. An inner pressure of the processing container 41 is reduced down to the atmospheric pressure (0.1 MPa). Next, the lid body 43 opens the opening 44 of the processing container 41, and the wafer W is taken out of the processing container 41.

In Step S205, the transfer device 132 receives the wafer W from the holding unit 42, and further carries the received wafer W out of the drying unit 4.

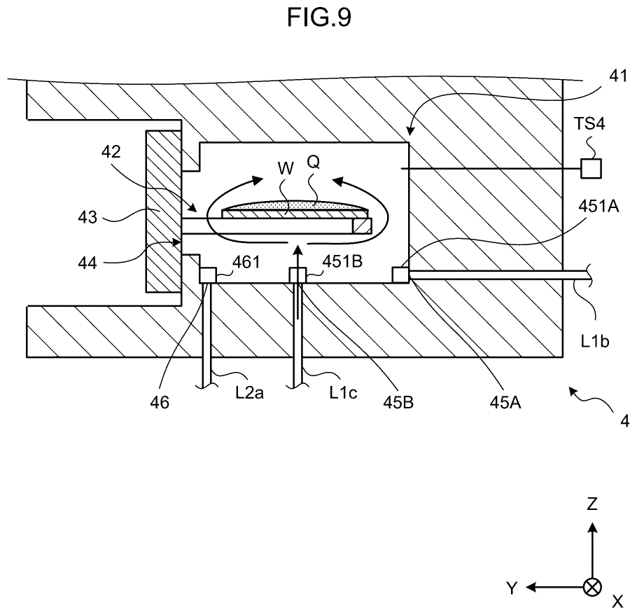

FIG. 9 is a schematic diagram illustrating an internal state of the processing container 41 in the pressure raising process. As described above, in the pressure raising process, process fluid is supplied to the processing container 41 from the below of the wafer W via the supply port 45B and the supply header 451B. In this case, flow of the process fluid is generated in the processing container 41 so as to go around the wafer W from a lower surface to an upper surface of the wafer W.

Thus, shearing force by the process fluid works on a surface of a liquid film of IPA (see liquid film Q illustrated in FIG. 9) which is formed on an upper surface of the wafer W. There presents possibility that IPA falls down form the wafer W due to the above-mentioned shearing force. In a case where IPA falls down from the wafer W, an amount of IPA on the wafer W becomes less than a proper amount, and thus there presents possibility that a pattern formed on a surface of the wafer W collapses.

Details thereof will be mentioned later, in accordance with the substrate processing system 1 according to the present disclosure, in the pressure raising process, it is possible to detect abnormality in a liquid film state such as falling down of IPA from the wafer W. In accordance with the substrate processing system 1 according to the present disclosure, in a case where the above-mentioned abnormality in a liquid film state is detected, if an adjusting process to be mentioned later is executed, it is possible to maintain the liquid film state to be normal. Thus, it is possible to prevent occurrence of the above-mentioned pattern collapse.

### Functions of Control Device

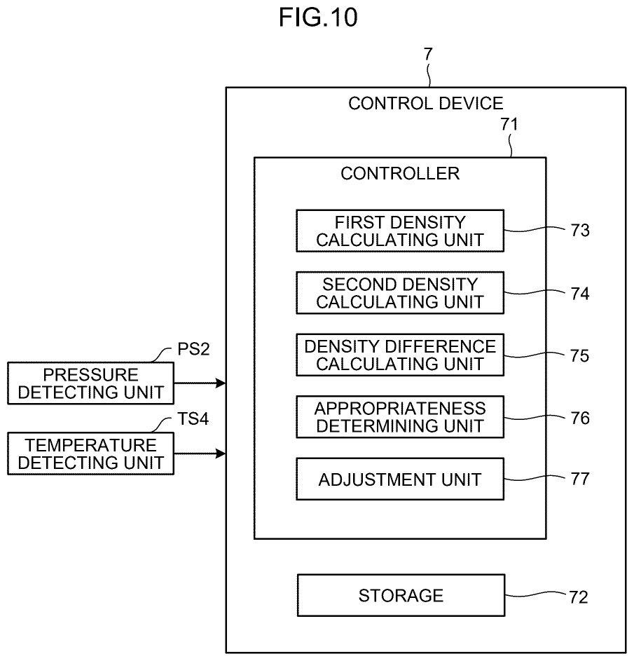

Functions of the control device 7 will be explained. FIG. 10 is a functional block diagram illustrating a configuration example of the control device 7 according to the first embodiment. The illustrated components of the devices illustrated in FIG. 10 are functionally conceptual, and thus they are not to be physically configured as illustrated in the drawings. All or some of the functional blocks can be configured by separating or integrating the apparatus functionally or physically in any unit. All or an arbitrary part of processing functions executed in each functional block is realized by a program executed in a CPU, or may be realized as hardware by a wired logic.

The control device 7 includes the controller 71 and the storage 72. The controller 71 includes a first density calculating unit 73, a second density calculating unit 74, a density difference calculating unit 75, an appropriateness determining unit 76, and an adjustment unit 77, for example.

In a pressure raising process of the drying process (hereinafter, may be referred to as “preprocessing”), which is executed in a state where a liquid film of IPA is not formed on the wafer W, the first density calculating unit 73 calculates first density data D₁ indicating time-dependent changes in a density of a process fluid on the basis of a first pressure P_{A} detected by the pressure sensor PS2 and a first temperature T_{A} detected by the temperature sensor TS4. Specifically, in a pressure raising process of preprocessing, the first density data D₁ is calculated per unit time interval on the basis of an equation of state to be mentioned later by using the first pressure P_{A} and the first temperature T_{A}.

Specifically, the above-mentioned preprocessing is executed with respect to the wafer W for preprocessing prior to a drying process with respect to the product wafer W. Note that the number of the wafers W to be preprocessed may be two or more. In other words, preprocessing may be executed with respect to each of the plurality of wafers W.

In this case, in each preprocessing, the first density calculating unit 73 calculates, per unit time interval, time-dependent change data of a density of process fluid in the processing container 41 by using the detected first pressure P_{A} and the detected first temperature T_{A}. Next, the first density calculating unit 73 may calculate the first density data D₁ on the basis of an average value at time points in the above-mentioned time-dependent change data of a density calculated in each preprocessing.

The storage 72 stores therein time-dependent change data of the first pressure P_{A} detected by the pressure sensor PS2, time-dependent change data of the first temperature T_{A} detected by the temperature sensor TS4, and the first density data D₁ calculated by the first density calculating unit 73.

In a pressure raising process of the drying process (hereinafter, may be referred to as “main process”) executed in a state where a liquid film of IPA is formed on the wafer W, the second density calculating unit 74 calculates second density data D₂ indicating time-dependent changes in a density of process fluid on the basis of a second pressure P_{B} detected by the pressure sensor PS2 and a second temperature T_{B} detected by the temperature sensor TS4. Specifically, the second density calculating unit 74 calculates, per unit time interval, the second density data D₂ on the basis of an equation of state to be mentioned later by using the second pressure P_{B} and the second temperature T_{B} in a pressure raising process in the main process.

Not that the above-mentioned main process specifically indicates a drying process that is executed with respect to the product wafer W. The above-mentioned main process is executed after the above-mentioned preprocessing.

The preprocessing and the main process are executed under the same drying process condition. The preprocessing and the main process may be executed with respect to the same drying unit 4, for example. The preprocessing and the main process may be executed on the same day, for example.

In the main process, the density difference calculating unit 75 calculates density difference data ΔD that is difference between the first density data D₁ stored in the storage 72 and the second density data D₂ calculated by the second density calculating unit 74. Specifically, in the second pressure raising process of the main process, the density difference calculating unit 75 calculates, per unit time interval, the density difference data ΔD by ΔD=D₁−D₂ with the use of the first density data D₁ and the second density data D₂.

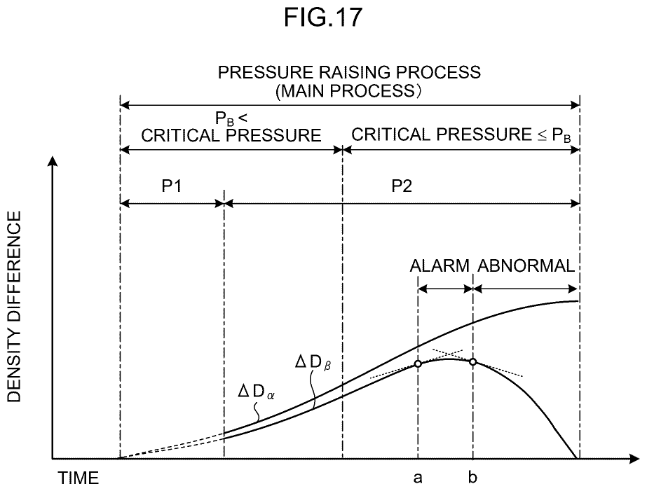

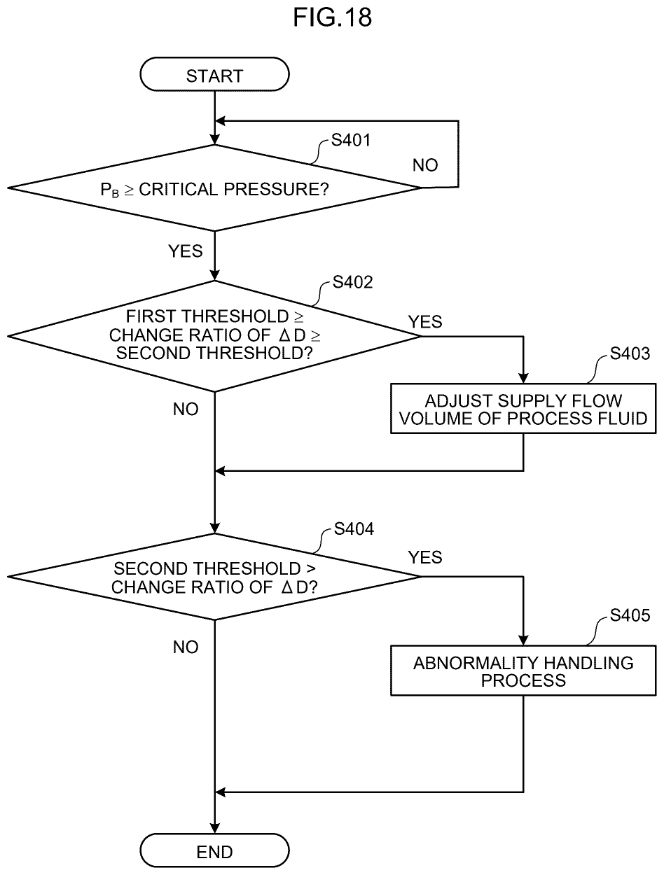

In the second pressure raising process of the main process, the appropriateness determining unit 76 determines whether or not the above-mentioned abnormality occurs in a liquid film state on the basis of the second pressure P_{B} and the density difference data ΔD. Specifically, the appropriateness determining unit 76 determines appropriateness of a liquid film state on the basis of the second pressure P_{B} and a temporal change ratio of the density difference data ΔD, and outputs an alarm or abnormality determination in accordance with determination result. A specific procedure for the appropriateness determination will be mentioned later with reference to FIG. 17 and FIG. 18.

In a case where an alarm is output by the appropriateness determining unit 76, in the second pressure raising process of the main process, the adjustment unit 77 adjusts at least one parameter value of a plurality of processing parameters that prescribe a condition of the drying process. The plurality of processing parameters includes a supply flow volume of process fluid to be supplied to the processing container 41, a temperature of process fluid to be supplied to the processing container 41, a liquid amount of a liquid film of IPA formed on the wafer W, and a temperature of the processing container 41, for example. According to the above-mentioned adjusting process, it is possible to maintain a liquid film state of IPA to be normal. A procedure for a specific adjusting process to be executed by the adjustment unit 77 will be mentioned later with reference to FIG. 17 and FIG. 18.

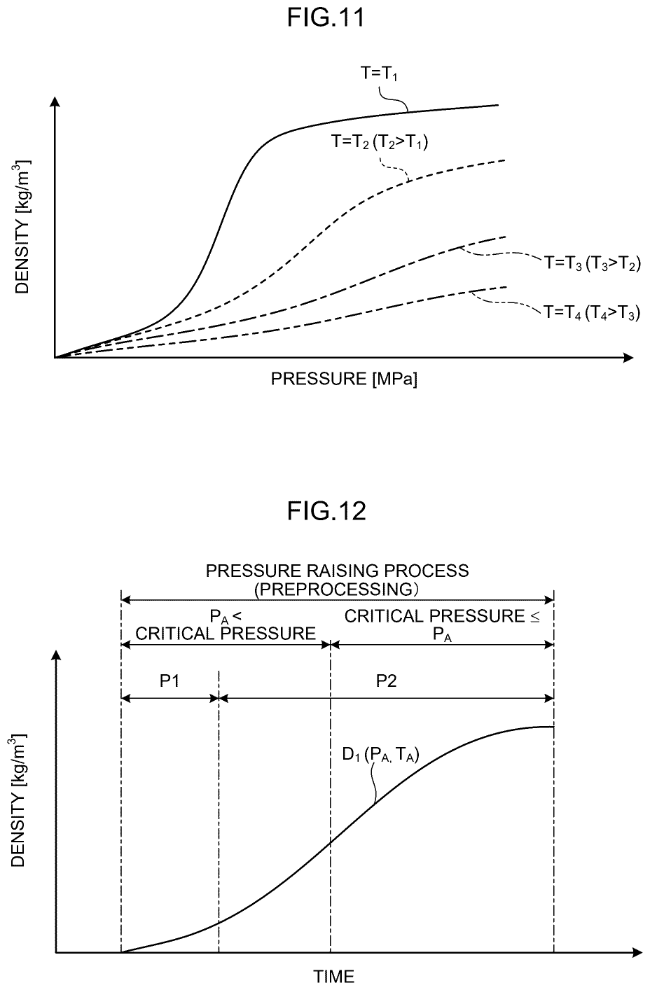

Herein, details of the first density data D₁, the second density data D₂, and the density difference data ΔD will be explained with reference to FIG. 11 to FIG. 14.

FIG. 11 is a diagram illustrating one example of relation between a density, a pressure, and a temperature in supercritical fluid. In FIG. 11, T indicates a temperature of supercritical fluid. A temperature T₁ is lower than a temperature T₂, the temperature T₂ is lower than a temperature T₃, and the temperature T₃ is lower than a temperature T₄. As illustrated in FIG. 11, in a case where a pressure is constant, the density is lower as the temperature is higher. In a case where a temperature is constant, a density is higher as a pressure higher. Relation between a density, a pressure, and a temperature of supercritical fluid is preliminarily obtained by an experiment or the like, and is preliminarily stored in the storage 72. The above-mentioned relation may be stored in the form of an equation. The equation is generally called as an equation of state.

FIG. 12 is a diagram illustrating one example of the first density data D₁. The first density data D₁ is calculated on the basis of an equation of state illustrated in FIG. 11 by using the above-mentioned first pressure P_{A} and the above-mentioned first temperature T_{A}. As illustrated in FIG. 12, a value of the first density data D₁ increases in accordance with a rise in the first pressure P_{A}. Note that FIG. 12 illustrates a region where the first pressure P_{A} is less than a critical pressure and a region where the first pressure P_{A} is equal to more than the critical pressure. Furthermore, in FIG. 12, a region P1 corresponds to the first pressure raising process, and a region P2 corresponds to the second pressure raising process.

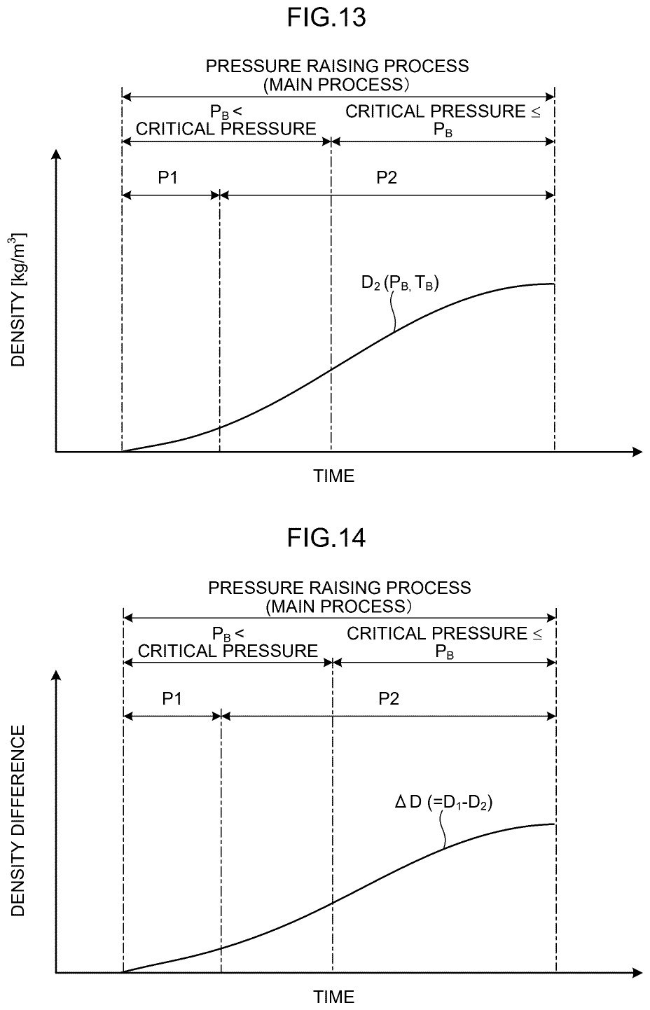

FIG. 13 is a diagram illustrating one example of the second density data D₂. The second density data D₂ is calculated from an equation of state illustrated in FIG. 11 by using the above-mentioned second pressure P_{B} and the above-mentioned second temperature T_{B}. As illustrated in FIG. 13, a value of the second density data D₂ increases in accordance with a rise in the second pressure P_{B}. Note that FIG. 13 illustrates a region where the second pressure P_{B} is less than a critical pressure and a region where the second pressure P_{B} is equal to or more than the critical pressure. Furthermore, in FIG. 13, the region P1 corresponds to the first pressure raising process, and the region P2 corresponds to the second pressure raising process.

In a pressure raising process of the main process, a part of process fluid dissolves in a liquid film of IPA. Thus, a value of the second pressure P_{B}, which is detected in the main process, is smaller than the first pressure P_{A} that is detected in preprocessing. Thus, a value of the second density data D₂ is smaller than a value of the first density data D₁.

FIG. 14 is a diagram illustrating one example of density difference data. The density difference data ΔD is calculated as ΔD=D₁−D₂ by using the first density data D₁ and the second density data D₂. Herein, ΔD is an amount that is proportional to an amount of process fluid dissolved in a liquid film of IPA in the second pressure raising process of the main process. As illustrated in FIG. 14, a value of ΔD increases in accordance with a rise in a pressure of the second pressure P_{B}.

### Functions of Control Device

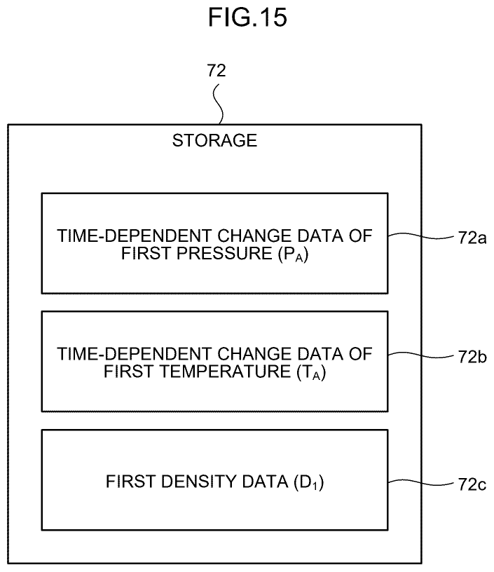

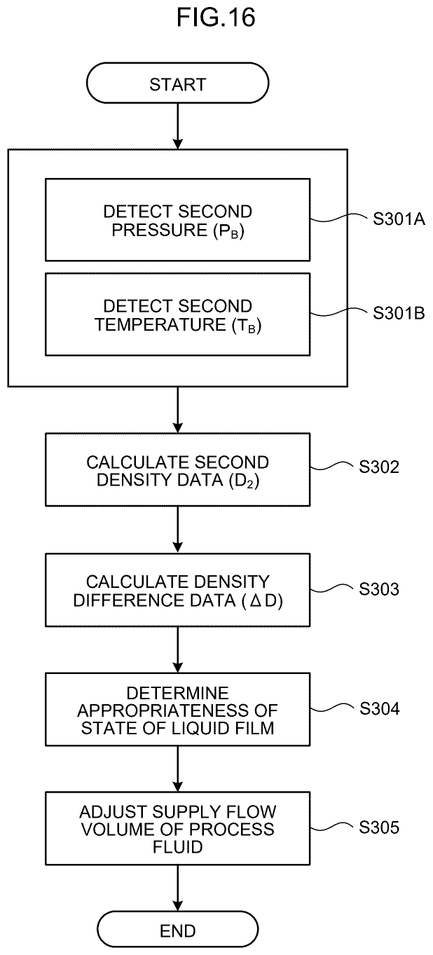

The outline of a procedure for a series of abnormality detections to be executed in the controller 71 according to the first embodiment will be explained with reference to FIG. 15 and FIG. 16.

For explanation of a procedure for a series of abnormality detections, an example of data stored in the storage 72 will be explained. FIG. 15 is a diagram illustrating an example of data to be stored in the storage 72 according to the first embodiment. As described above, the storage 72 preliminarily stores therein time-dependent change data (see data 72a illustrated in FIG. 15) of the first pressure P_{A} detected by the pressure sensor PS2, time-dependent change data (see data 72b illustrated in FIG. 15) of the first temperature T_{A} detected by the temperature sensor TS4, and the first density data D₁ (see data 72c illustrated in FIG. 15) calculated by the first density calculating unit 73.

Next, the outline of a procedure for a series of abnormality detections will be explained. FIG. 16 is a flowchart illustrating a procedure for a series of abnormality detections to be executed in the controller 71 according to the first embodiment. Note that a process of each of the following Steps is executed, per unit time interval, in the second pressure raising process of the main process.

The pressure sensor PS2 detects the second pressure P_{B} (Step S301A), and the temperature sensor TS4 detects the second temperature T_{B} (Step S301B).

Subsequently, the second density calculating unit 74 calculates the second density data D₂ on the basis of an equation of state illustrated in FIG. 11 by suing the second pressure P_{B} detected in Step S301A and the second temperature T_{B} detected in Step S301B (Step S302).

Subsequently, the density difference calculating unit 75 calculates the density difference data ΔD on the basis of an equation of state by using the first density data D₁ preliminarily stored in the storage 72 and the second density data D₂ calculated in Step S302 (Step S303).

The appropriateness determining unit 76 determines appropriateness of a state of a liquid film of IPA on the basis of the second pressure P_{B} detected in Step S301A and a temporal change ratio of the density difference data ΔD calculated in Step S303, so as to output an alarm or abnormality determination (Step S304). A Specific procedure for appropriateness determinations will be mentioned later with reference to FIG. 17 and FIG. 18.

In a case where an alarm by the appropriateness determining unit 76 is output in Step S304, the adjustment unit 77 adjusts a supply flow volume of process fluid to be supplied to the processing container 41 (Step S305). Thus, a liquid film state of IPA on the wafer W is maintained to be normal.

In the above-mentioned Step S305, the adjustment unit 77 may adjust at least one of the above-mentioned processing parameters that prescribes conditions of the drying process. Hereinafter, a case will be explained where a supply flow volume of process fluid is adjusted as one example. Note that a specific procedure for adjusting a supply flow volume will be mentioned later with reference to FIG. 17 and FIG. 18.

Details of appropriateness determination to be executed in the appropriateness determining unit 76 according to the first embodiment will be explained with reference to FIG. 17 and FIG. 18. FIG. 17 is a diagram illustrating one example of the density difference data ΔD including abnormality in the drying process. In FIG. 17, ΔD_{α} indicates one example of time-dependent changes in the density difference data ΔD in a case where not including abnormality in a liquid film state in a pressure raising process of the main process. Additionally, ΔD_{β} indicates one example of time-dependent changes in the density difference data ΔD in a case where including abnormality in a liquid film state in a pressure raising process of the main process. Hereinafter, details of appropriateness determination will be explained while exemplifying the density difference data ΔD_{β}.

Features of the density difference data ΔD_{β} will be explained. As described above, in the second pressure raising process of the main process, the density difference data ΔD is proportional to an amount of process fluid dissolved in a liquid film of IPA. For example, in a case where liquid of IPA has fallen off from an upper surface of the wafer W, the fallen-off IPA vaporizes in the processing container 41. Thus, a liquid amount of a liquid film state of IPA reduces, and thus an amount of process fluid to be dissolved in the liquid film of IPA also reduces. Therefore, as illustrated in FIG. 17, in the density difference data ΔD_{β}, in a case where IPA begins to fall off from the wafer W, a temporal change ratio thereof, in other words, an inclination of ΔD_{β} illustrated in FIG. 17 begins to reduce. In a case where whole IPA has fallen off from the wafer W, a value of the density difference data ΔD_{β} becomes “0”.

For example, the appropriateness determining unit 76 outputs an alarm in a case where a temporal change ratio of the density difference data ΔD_{β} is equal to or less than a first threshold and further is equal to or more than a second threshold that is smaller than the first threshold. Specifically, the first threshold may be 0.1, for example. Additionally, the second threshold may be −0.1, for example. In other words, the appropriateness determining unit 76 outputs an alarm in a case where a temporal change ratio of the density difference data ΔD_{β} becomes a value of approximately “0”. As described above, the appropriateness determining unit 76 is capable of detecting occurrence of falling off of IPA from the wafer W.

Note that in FIG. 17, a time interval a indicates an elapsed time interval from a main process start timing when a temporal change ratio of the density difference data ΔD_{β} becomes the first threshold. A time interval b indicates an elapsed time interval from a main process start timing when a temporal change ratio of the density difference data ΔD_{β} becomes the second threshold.

For example, the appropriateness determining unit 76 outputs abnormality determination in a case where a temporal change ratio of the density difference data ΔD_{β} is equal to or less than the second threshold. As described above, the appropriateness determining unit 76 is capable of detecting abnormality in a liquid film state in a case where excess falling off of IPA from the wafer W has occurred.

For example, the appropriateness determining unit 76 may output information indicating the fact that an alarm or abnormality determination is output to an external device or the like. In this way, an operator may be informed of occurrence of an alarm or abnormality determination.

Next, a procedure for appropriateness determination to be executed by the appropriateness determining unit 76 will be explained. FIG. 18 is a flowchart illustrating a procedure for appropriateness determination to be executed in the appropriateness determining unit 76 according to the first embodiment.

The controller 71 determines whether or not the second pressure P_{B} is equal to or more than a critical pressure (Step S401). In a case where the second pressure P_{B} is not equal to or more than the critical pressure (Step S401: No), the controller 71 repeatedly executes Step S401.

Subsequently, in a case where the second pressure P_{B} is equal to or more than the critical pressure (Step S401: Yes), the appropriateness determining unit 76 determines whether or not a temporal change ratio of the density difference data ΔD is equal to or less than the first threshold and further is equal to or more than the second threshold (Step S402).

In Step S402, in a case where a temporal change ratio of the density difference data ΔD is within a range of the above-mentioned threshold (Step S402: Yes), the appropriateness determining unit 76 outputs an alarm. In a case where an alarm is output, the adjustment unit 77 reduces a supply flow volume of process fluid to be supplied to the processing container 41, for example (Step S403).

Specifically, the adjustment unit 77 may temporarily stop supplying process fluid by the supply line L1, for example, and then may adjust a parameter value of a supply flow volume so as to restart supply of the process fluid. In a case where an alarm is output again after the parameter value is adjusted, the adjustment unit 77 may control an opening degree of the decompression valve 53 in a state where the open/close valve 52c of the open/close line L2a is opened, for example, so as to reduce a supply flow volume of process fluid to be supplied to the processing container 41.

According to the above-mentioned configuration, it is possible to reduce the above-mentioned shearing force due to process fluid, which works on a surface of a liquid film of IPA. Thus, it is possible to reduce occurrence of falling off of IPA from the wafer W.

The above-mentioned shearing force due to process fluid is proportional to the magnitude of a diffusion speed N that indicates a speed at which IPA liquid diffuses into the gaseous process fluid in the processing container 41. The above-mentioned diffusion speed N can be calculated by N=T^{(2/3)}ρ^{(1/6)}μ^{(-5/6)}μ^{(1/2)}L^{(-1/2)} by using a temperature T, a density ρ, and a viscosity μ of mixed fluid of diffused IPA and the gaseous process fluid, a supply flow volume u of the process fluid to the processing container 41, and an interval L between an upper surface of the processing container 41 and an upper surface of a liquid film of IPA.

Note that the adjustment unit 77 may adjust a heating temperature of the above-mentioned heater arranged on the supply line L1 so as to reduce a temperature of process fluid to be supplied to the processing container 41. The processing container 41 may be connected with a not-illustrated heating mechanism, and further the adjustment unit 77 may adjust a heating temperature of the above-mentioned heating mechanism so as to reduce a temperature of the processing container 41. According to the above-mentioned configuration, it is possible to reduce shearing force due to process fluid.

In the liquid-film forming process by the liquid processing units 2, the adjustment unit 77 may reduce a supply flow volume of IPA to be supplied to an upper surface of the wafer W. Specifically, the adjustment unit 77 may adjust values of parameters that prescribe a supply flow volume of IPA supplied by the liquid processing unit 2. According to the above-mentioned configuration, in substrate processing executed after the main process in which an alarm is output, it is possible to reduce a supply flow volume of IPA, which is supplied by the liquid processing unit 2. As described above, a liquid amount of a liquid film of IPA is reduced, so that it is possible to reduce occurrence of falling off of IPA.

Note that the storage 72 may store therein identification information on the wafer W on which an adjusting process is executed by the adjustment unit 77 in the main process. Specifically, the above-mentioned identification information may include identification numbers associated with the respective wafers W, for example.

In Step S402, in a case where a temporal change ratio of the density difference data ΔD is out of a range of the above-mentioned threshold (Step S402: No), or in a case where a process of Step S403 has completed, the appropriateness determining unit 76 determines whether or not a temporal change ratio of the density difference data ΔD is equal to or less than the second threshold (Step S404).

In Step S404, in a case where a temporal change ratio of the density difference data ΔD is equal to or less than the second threshold (Step S404: Yes), the appropriateness determining unit 76 outputs abnormality determination. In a case where abnormality determination is output, an abnormality handling process is executed (Step S405). Specifically, an abnormality handling process is executed, which is for discarding the wafer W determined to be abnormal as a defective product, for example. Or, as the abnormality handling process, for example, usage of the liquid processing unit 2 may be stopped, which has executed a liquid-film forming process on the wafer W regarding which abnormality determination is output.

In Step S404, in a case where a temporal change ratio of the density difference data ΔD is not equal to or less than the second threshold (Step S404: No), or in a case where the process of Step S405 has completed; the appropriateness determining unit 76 ends a series of appropriateness determinations.

### Second Embodiment

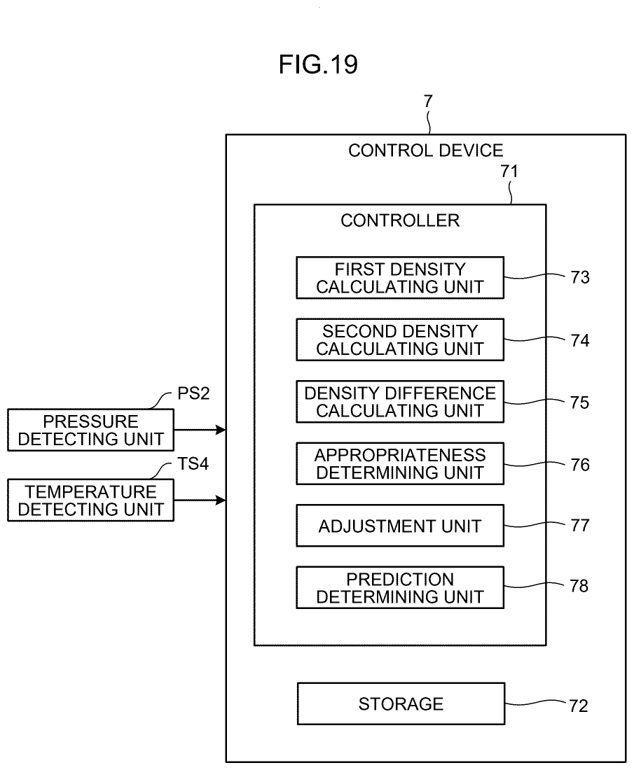

The controller 71 according to a second embodiment will be explained with reference to FIG. 19 to FIG. 21. FIG. 19 is a functional block diagram illustrating a configuration example of the control device 7 according to the second embodiment. As illustrated in FIG. 19, the controller 71 according to the second embodiment further includes a prediction determining unit 78 that predicts an output of an alarm by the appropriateness determining unit 76.

The prediction determining unit 78 predicts an output of an alarm by the appropriateness determining unit 76 on the basis of the above-mentioned shearing force due to process fluid, which is calculated on the basis of a supply flow volume of the process fluid supplied to the processing container 41 and surface tension of a liquid film of IPA, which is calculated on the basis of the second density data D₂, and further outputs a warning.

The storage 72 according to the second embodiment may preliminarily store therein information on correlation between a supply flow volume of process fluid and shearing force working on a liquid film surface of IPA due to process fluid. The above-mentioned information on correlation may be information related to an occurrence distribution of the above-mentioned shearing force calculated by simulation for each of conditions of supply flow volumes of different process fluids, for example.

The prediction determining unit 78 may calculate a maximum value of the above-mentioned shearing force working on a surface of a liquid film of IPA on the basis of a supply flow volume of process fluid by using information related to an occurrence distribution of the above-mentioned shearing force stored in the storage 72.

The prediction determining unit 78 may calculate a surface tension σ of a liquid film of IPA by using the second density data D₂ and a well-known calculating equation for calculating a surface tension of ethanol in CO₂ atmosphere, for example. Specifically, for example, in a case where a=−0.0042, b=1123, c=0.27, d=72, f=150 are assumed, the prediction determining unit 78 may calculate a surface tension σ on the basis of σ=c+(d−c)/(1+exp(−a(D₂−b)))^{f}. Note that the above-mentioned a, b, c, d, and f are constant values described in the well-known equation.

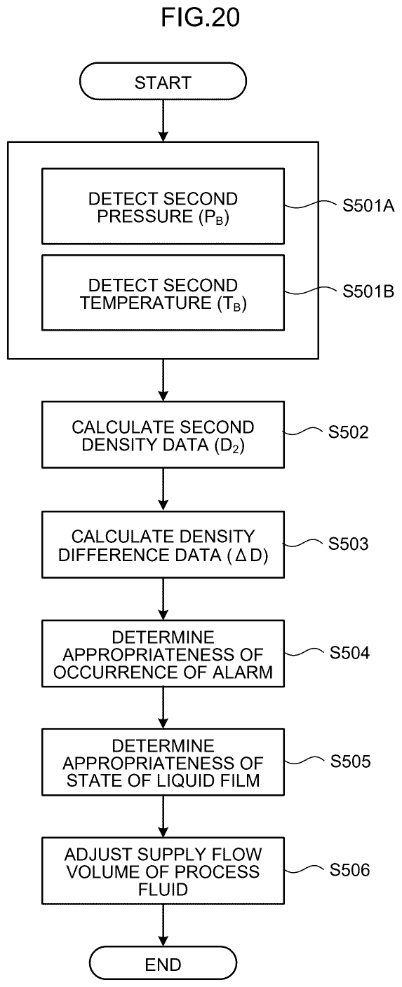

FIG. 20 is a flowchart illustrating a procedure for a series of abnormality detections to be executed in the controller 71 according to the second embodiment. In FIG. 20, processes other than that in Step S504 are the same as the processes in Step S301A to Step S305 illustrated in FIG. 16, and thus explanation thereof is omitted.

After a process for calculating the density difference data ΔD of Step S503, and before a process for appropriateness determination of a liquid film state of Step S505, the prediction determining unit 78 may predict an output of an alarm by the appropriateness determining unit 76, and further may output a warning (Step S504).

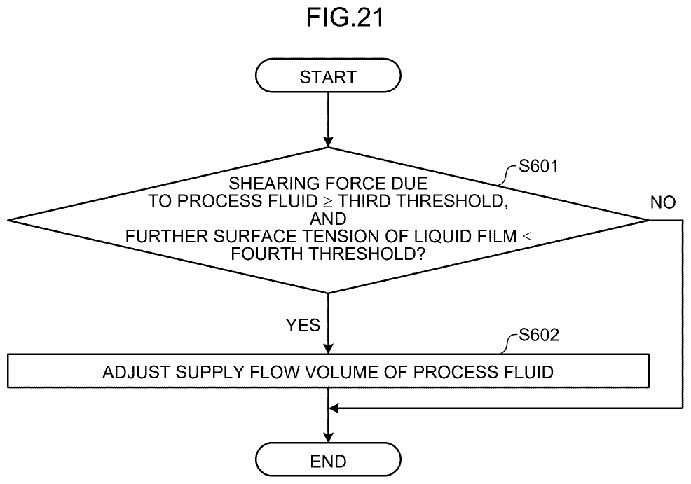

FIG. 21 is a flowchart illustrating a procedure for estimation determination to be executed by the prediction determining unit 78 according to the second embodiment. Note that a process in Step S602 illustrated in FIG. 21 is the same as the process in Step S403 illustrated in FIG. 18.

The prediction determining unit 78 first determines whether or not the above-mentioned calculated maximum value of shearing force is equal to or more than the preset third threshold, and further the above-mentioned calculated liquid film of IPA is equal to or less than the fourth threshold (Step S601).

In Step S601, in a case where the above-mentioned maximum value of shearing force is less than the third threshold, and further the above-mentioned surface tension σ of a liquid film of IPA is larger than the fourth threshold (Step S601: No), the prediction determining unit 78 ends the determination process.

In Step S601, in a case where the above-mentioned maximum value of shearing force is equal to or more than the third threshold, and further the above-mentioned surface tension σ of a liquid film of IPA is equal to or less than the fourth threshold (Step S601: Yes), the prediction determining unit 78 determines that there presents possibility that IPA falls off from the wafer W, in other words, possibility that an alarm is output from the appropriateness determining unit 76, and further outputs a warning. For example, in a case where a warning is output, the adjustment unit 77 reduces a supply flow volume of process fluid to be supplied to the processing container 41 (Step S602).

Note that a value of the third threshold may be the same as a value of the fourth threshold. In other words, in this case, the prediction determining unit 78 outputs a warning in a case where the above-mentioned maximum value of shearing force is larger than the above-mentioned surface tension σ.

According to the above-mentioned configuration, it is possible to predict occurrence of falling off of IPA from the wafer W before an alarm is output from the appropriateness determining unit 76. Thus, it is possible to more appropriately reduce occurrence of abnormality in a liquid film state.

### Other Modification

So far, an example has been explained in which the adjustment unit 77 predicts occurrence of an alarm by the appropriateness determining unit 76 with the use of information on correlation between a supply flow volume of process fluid and the above-mentioned shearing force of the process fluid. Not limited thereto, on the basis of information on correlation between a liquid film state of IPA preliminarily stored in the storage 72 and a parameter value of the above-mentioned processing parameter, the adjustment unit 77 may adjust the above-mentioned parameter value so as to maintain a liquid film state of IPA to be normal.

Specifically, the above-mentioned information on correlation may be information on a parameter value of a processing parameter and an occurrence distribution of shearing force due to process fluid working on a liquid film surface of IPA, for example. Or the above-mentioned information on correlation may be information on correlation between a parameter value of a processing parameter in the main process and an occurrence distribution of pattern collapse having actually occurred in the above-mentioned main process.

The storage 72 may store therein, as big data, information on the above-mentioned occurrence distributions of shearing force in the plurality of main processes, the above-mentioned occurrence distributions of pattern collapse, and the like; and information on parameter values of the above-mentioned processing parameters in the plurality of main processes.

The adjustment unit 77 may analyze the above-mentioned big data by using AI so as to control an output of a warning by the prediction determining unit 78. In other words, for example, the adjustment unit 77 may comprehensively analyze information included in the above-mentioned big data, and execute machine learning thereon so as to calculate an output condition of the above-mentioned warning and the like.

So far, details of the present disclosure have been explained; however, the present disclosure is not limited to the above-mentioned embodiments, and various substitutions and changes in the form of the embodiments described herein may be made without departing from the spirit of the disclosure.

Therefore, the invention in its broader aspects is not limited to the specific details and representative embodiments shown and described herein. Additional advantages and modifications will readily occur to those skilled in the art. Accordingly, various modifications may be made without departing from the spirit or scope of the general inventive concept as defined by the appended claims and their equivalents.

Note that the following configurations may be employed for the present technology:

(1)

A substrate processing apparatus including:
a processing container into which process fluid is supplied and a liquid film of drying liquid formed on a substrate is replaced with the process fluid in a supercritical state to execute a drying process on the substrate;
a pressure detecting unit that detects a pressure of the process fluid in the processing container;
a temperature detecting unit that detects a temperature of the process fluid in the processing container; and
a controller, wherein
the drying process includes:
   a pressure raising process for supplying the process fluid into the processing container to raise an internal pressure of the processing container up to a set pressure equal to or more than a critical pressure,
the controller includes:
   a first density calculating unit that calculates first density data indicating a time-dependent change in a density of the process fluid based on a first pressure detected by the pressure detecting unit and a first temperature detected by the temperature detecting unit in the pressure raising process of preprocessing that is the drying process executed in a state where a liquid film of the drying liquid is not formed on the substrate;
   a second density calculating unit that calculates second density data indicating a time-dependent change in a density of the process fluid based on a second pressure detected by the pressure detecting unit and a second temperature detected by the temperature detecting unit in the pressure raising process of a main process that is the drying process executed in a state where a liquid film of the drying liquid is formed on the substrate;
   a density difference calculating unit that calculates density difference data that is difference between the first density data and the second density data; and
   an appropriateness determining unit that determines, based on the density difference data and in the main process, appropriateness of the state of the liquid film of the drying liquid formed on the substrate.
      (2)

The substrate processing apparatus according to (1), wherein
the pressure raising process includes:
   a first pressure raising process for raising an internal pressure of the processing container while discharging, from the processing container, a part of the process fluid to be supplied to the processing container; and
   a second pressure raising process for raising, after the first pressure raising process, an internal pressure of the processing container up to a set pressure equal to or more than a critical pressure in a state where discharging of the process fluid from the processing container is stopped, and
the density difference calculating unit calculates the density difference data in the second pressure raising process.
   (3)

The substrate processing apparatus according to (2), wherein
a value in the first density data is larger than a value in the second density data in each of elapsed time intervals from a start timing of the second pressure raising process.
   (4)

The substrate processing apparatus according to (3) further including:
a storage, wherein
the density difference calculating unit calculates the density difference data by using the first density data preliminarily stored in the storage, and the second density data calculated by the second density calculating unit.
   (5)

The substrate processing apparatus according to (3) or (4), wherein
based on the second pressure and a temporal change ratio of the density difference data, the appropriateness determining unit determines appropriateness of a state of the liquid film of the drying liquid.
   (6)

The substrate processing apparatus according to (5), wherein
in a case where the second pressure is equal to or more than a critical pressure, the appropriateness determining unit outputs an alarm when a temporal change ratio of the density difference data is equal to or less than a first threshold and further is equal to or more than a second threshold that is smaller than the first threshold, and
the appropriateness determining unit determines that the drying process is abnormal when a temporal change ratio of the density difference data is less than the second threshold.
   (7)

The substrate processing apparatus according to (6), wherein
the controller further includes:
   a prediction determining unit that predicts occurrence of the alarm based on shearing force in a liquid film interface of the drying liquid due to the process fluid, which is calculated based on a supply flow volume of the process fluid, and surface tension of the liquid film of the drying liquid, which is calculated based on the second density data; and further outputs a warning.
      (8)

The substrate processing apparatus according to (7), wherein
the controller further includes:
   an adjustment unit that adjusts, in the main process and based on the alarm or the warning, a parameter value of at least one of a supply flow volume of the process fluid to be supplied to the processing container, a temperature of the process fluid to be supplied to the processing container, a liquid amount of a liquid film of the drying liquid formed on the substrate, and a temperature of the processing container among a plurality of processing parameters of the drying process.
      (9)

The substrate processing apparatus according to (8), wherein
in a case where the alarm is output by the appropriateness determining unit, the adjustment unit adjusts a supply flow volume of the process fluid to be supplied to the processing container.
   (10)

The substrate processing apparatus according to (8) or (9), wherein
in a case where the warning is output from the prediction determining unit, the adjustment unit adjusts a supply flow volume of the process fluid.
   (11)

The substrate processing apparatus according to (8) further including:
a storage, wherein
based on correlation between a state of a liquid film of the drying liquid preliminarily stored in the storage and a parameter value of the processing parameter, the adjustment unit adjusts the parameter value.
   (12)

The substrate processing apparatus according to any one of (1) to (11), wherein
the process fluid includes CO₂.
   (13)

A substrate processing method to be executed by a substrate processing apparatus comprising: a processing container into which process fluid is supplied and a liquid film of drying liquid formed on a substrate is replaced with the process fluid in a supercritical state to execute a drying process on the substrate; a pressure detecting unit that detects a pressure of the process fluid in the processing container; a temperature detecting unit that detects a temperature of the process fluid in the processing container; and a controller, wherein
the drying process includes:
   a pressure raising process for supplying the process fluid into the processing container to raise an internal pressure of the processing container up to a set pressure equal to or more than a critical pressure,
the controller executes a process comprising:
   calculating first density data indicating a time-dependent change in a density of the process fluid based on a first pressure detected by the pressure detecting unit and a first temperature detected by the temperature detecting unit in the pressure raising process of preprocessing that is the drying process executed in a state where a liquid film of the drying liquid is not formed on the substrate,
   calculating second density data indicating a time-dependent change in a density of the process fluid based on a second pressure detected by the pressure detecting unit and a second temperature detected by the temperature detecting unit in the pressure raising process of a main process that is the drying process executed in a state where a liquid film of the drying liquid is formed on the substrate,
   calculating density difference data that is difference between the first density data and the second density data, and
   based on the density difference data and in the main process, determining appropriateness of the state of the liquid film of the drying liquid formed on the substrate.

What is claimed is:

1. A substrate processing apparatus comprising:
a processing container into which process fluid is supplied and a liquid film of drying liquid formed on a substrate is replaced with the process fluid in a supercritical state to execute a drying process on the substrate;
a pressure detecting unit that detects a pressure of the process fluid in the processing container;
a temperature detecting unit that detects a temperature of the process fluid in the processing container; and
a controller, wherein
the drying process includes:
a pressure raising process for supplying the process fluid into the processing container to raise an internal pressure of the processing container up to a set pressure equal to or more than a critical pressure, and
the controller includes:
a first density calculating unit that calculates first density data indicating a time-dependent change in a density of the process fluid based on a first pressure detected by the pressure detecting unit and a first temperature detected by the temperature detecting unit in the pressure raising process of preprocessing that is the drying process executed in a state where a liquid film of the drying liquid is not formed on the substrate;
a second density calculating unit that calculates second density data indicating a time-dependent change in a density of the process fluid based on a second pressure detected by the pressure detecting unit and a second temperature detected by the temperature detecting unit in the pressure raising process of a main process that is the drying process executed in a state where a liquid film of the drying liquid is formed on the substrate;
a density difference calculating unit that calculates density difference data that is difference between the first density data and the second density data; and
an appropriateness determining unit that determines, based on the density difference data and in the main process, appropriateness of the state of the liquid film of the drying liquid formed on the substrate.

2. The substrate processing apparatus according to claim 1, wherein
the pressure raising process includes:
a first pressure raising process for raising an internal pressure of the processing container while discharging, from the processing container, a part of the process fluid to be supplied to the processing container; and
a second pressure raising process for raising, after the first pressure raising process, an internal pressure of the processing container up to a set pressure equal to or more than a critical pressure in a state where discharging of the process fluid from the processing container is stopped, and
the density difference calculating unit calculates the density difference data in the second pressure raising process.

3. The substrate processing apparatus according to claim 2, wherein
a value in the first density data is larger than a value in the second density data in each of elapsed time intervals from a start timing of the second pressure raising process.

4. The substrate processing apparatus according to claim 3 further comprising:
a storage, wherein
the density difference calculating unit calculates the density difference data by using the first density data preliminarily stored in the storage, and the second density data calculated by the second density calculating unit.

5. The substrate processing apparatus according to claim 3, wherein
based on the second pressure and a temporal change ratio of the density difference data, the appropriateness determining unit determines appropriateness of a state of the liquid film of the drying liquid.

6. The substrate processing apparatus according to claim 5, wherein
in a case where the second pressure is equal to or more than a critical pressure, the appropriateness determining unit outputs an alarm when a temporal change ratio of the density difference data is equal to or less than a first threshold and further is equal to or more than a second threshold that is smaller than the first threshold, and
the appropriateness determining unit determines that the drying process is abnormal when a temporal change ratio of the density difference data is less than the second threshold.

7. The substrate processing apparatus according to claim 6, wherein
the controller further includes:
a prediction determining unit that predicts occurrence of the alarm based on shearing force in a liquid film interface of the drying liquid due to the process fluid, which is calculated based on a supply flow volume of the process fluid, and surface tension of the liquid film of the drying liquid, which is calculated based on the second density data; and further outputs a warning.

8. The substrate processing apparatus according to claim 7, wherein
the controller further includes:
an adjustment unit that adjusts, in the main process and based on the alarm or the warning, a parameter value of at least one of a supply flow volume of the process fluid to be supplied to the processing container, a temperature of the process fluid to be supplied to the processing container, a liquid amount of a liquid film of the drying liquid formed on the substrate, and a temperature of the processing container among a plurality of processing parameters of the drying process.

9. The substrate processing apparatus according to claim 8, wherein
in a case where the alarm is output by the appropriateness determining unit, the adjustment unit adjusts a supply flow volume of the process fluid to be supplied to the processing container.

10. The substrate processing apparatus according to claim 8, wherein
in a case where the warning is output from the prediction determining unit, the adjustment unit adjusts a supply flow volume of the process fluid.

11. The substrate processing apparatus according to claim 8 further comprising:
a storage, wherein
based on correlation between a state of a liquid film of the drying liquid preliminarily stored in the storage and a parameter value of the processing parameter, the adjustment unit adjusts the parameter value.

12. The substrate processing apparatus according to claim 1, wherein
the process fluid includes CO₂.

13. A substrate processing method to be executed by a substrate processing apparatus comprising: a processing container into which process fluid is supplied and a liquid film of drying liquid formed on a substrate is replaced with the process fluid in a supercritical state to execute a drying process on the substrate; a pressure detecting unit that detects a pressure of the process fluid in the processing container; a temperature detecting unit that detects a temperature of the process fluid in the processing container; and a controller, wherein
the drying process includes:
a pressure raising process for supplying the process fluid into the processing container to raise an internal pressure of the processing container up to a set pressure equal to or more than a critical pressure,
the controller executes a process comprising:
calculating first density data indicating a time-dependent change in a density of the process fluid based on a first pressure detected by the pressure detecting unit and a first temperature detected by the temperature detecting unit in the pressure raising process of preprocessing that is the drying process executed in a state where a liquid film of the drying liquid is not formed on the substrate,
calculating second density data indicating a time-dependent change in a density of the process fluid based on a second pressure detected by the pressure detecting unit and a second temperature detected by the temperature detecting unit in the pressure raising process of a main process that is the drying process executed in a state where a liquid film of the drying liquid is formed on the substrate,
calculating density difference data that is difference between the first density data and the second density data, and
based on the density difference data and in the main process, determining appropriateness of the state of the liquid film of the drying liquid formed on the substrate.
